(19) United States
(12) Patent Application Publication
(10) Pub. No.: US 2026/0218946 A1
(43) Pub. Date: Jul. 30, 2026

(54) THERMOELECTRIC ELEMENT AND REFRIGERATOR INCLUDING THE SAME

(71) Applicant: SAMSUNG ELECTRONICS CO., LTD., Suwon-si (KR)

(72) Inventors: Junwoo SONG, Suwon-si (KR); Jaeik YOON, Suwon-si (KR); Jino KIM, Suwon-si (KR); Kwangjoo KIM, Suwon-si (KR)

(73) Assignee: SAMSUNG ELECTRONICS CO., LTD., Suwon-si (KR)

(21) Appl. No.: 19/451,508

(22) Filed: Jan. 16, 2026

Related U.S. Application Data
(63) Continuation of application No. PCT/KR2025/022307, filed on Dec. 19, 2025.

(30) Foreign Application Priority Data
Jan. 24, 2025 (KR) 10-2025-0011548

(51) Int. Cl. F25B 21/02; B22F 3/20; H10N 10/01; H10N 10/852

(52) U.S. Cl. CPC F25B 21/02; H10N 10/01; H10N 10/852; B22F 2003/208

(57) ABSTRACT

A method for manufacturing a thermoelectric element, the method including preparing a Bi—Te based alloy material that includes Se in a range of 0.1 to 0.5 mol. % based on total moles of the Bi—Te based alloy material; primarily crushing the Bi—Te based alloy material between a pair of crushing plates having a gap between the crushing plates set to 1 mm to 5 mm, so as to form primarily crushed alloy pieces having a first length; and secondarily crushing the primarily crushed alloy pieces between a pair of disks having a gap between the disks set to 0.1 mm to 10 mm, so as to form an alloy powder including plate-shaped alloy powder having a second length smaller than the first length.

### CROSS-REFERENCE TO RELATED APPLICATIONS

This application is a by-pass continuation application of International Application No. PCT/KR2025/022307, filed on Dec. 19, 2025, which is based on and claims priority to Korean Patent Application No. 10-2025-0011548, filed on Jan. 24, 2025, in the Ministry of Intellectual Property, the disclosures of which are incorporated by reference herein their entireties.

### TECHNICAL FIELD

An embodiment of the disclosure relates to a thermoelectric element and a refrigerator including the same.

### BACKGROUND ART

Generally, a thermoelectric element is called by various names such as a thermoelectric module, a Peltier element, a thermoelectric cooler (TEC), or a thermoelectric module (TEM). A thermoelectric element is composed of N-type and P-type thermoelectric materials (thermoelectric legs) and electrodes such as nickel (Ni) and cobalt (Co).

When a direct current (DC) voltage is applied to two opposite ends of a thermoelectric element, heat moves from a heat absorbing portion to a heat generating portion according to a flow of electrons in the N-type thermoelectric material and according to a flow of holes in the P-type thermoelectric material. In some cases, when the polarity of an applied voltage is changed, positions of the heat absorbing portion and the heat generating portion are switched with each other, and a flow of heat is also reversed. Through this principle, a thermoelectric element may provide a role of a heat pump that absorbs heat from a low-temperature heat source and provides heat to a high-temperature heat source, or provide a role of a thermoelectric generation (TEG) that generates an electromotive force by moving electrons and holes inside thermoelectric element due to a temperature difference between two opposite ends.

As demand for thermoelectric elements increases, there is an increasing demand for thermoelectric materials with excellent thermoelectric performance (e.g., Seebeck coefficient, electrical conductivity, thermal conductivity, and mobility).

### DISCLOSURE OF INVENTION

### Solution to Problems

A method for manufacturing a thermoelectric element 100 according to an embodiment of the disclosure may comprises preparing a Bi—Te based alloy material that includes Se in a range of 0.1 to 0.5 mol. % based on total moles of the Bi—Te based alloy material; primarily crushing the Bi—Te based alloy material between a pair of crushing plates having a gap between the crushing plates set to 1 mm to 5 mm, so as to form primarily crushed alloy pieces having a first length; and secondarily crushing the primarily crushed alloy pieces between a pair of disks having a gap between the disks set to 0.1 mm to 10 mm, so as to form an alloy powder including plate-shaped alloy powder having a second length smaller than the first length.

A refrigerator according to an embodiment of the disclosure may include a main body, a door rotatably connected to open and close the main body, a storage compartment disposed inside the main body and storing food, and a cold air supply device configured to supply cold air to the storage compartment and including a thermoelectric element. The thermoelectric element may include a Bi—Te based thermoelectric leg. The Bi—Te based thermoelectric leg may include Se in a range of 0.1 to 0.5 mol. % based on total moles of the Bi—Te based thermoelectric leg, the Bi—Te based thermoelectric leg is a sintered material composed of plate-shaped alloy powder. The length of each of the plate-shaped alloy powder forming the sintered material may be 200 μm or less.

A thermoelectric element according to an embodiment of the disclosure may include a Bi—Te based thermoelectric leg. The Bi—Te based thermoelectric leg may include selenium (Se) in a range of 0.1 to 0.5 mol. % based on total moles of the Bi—Te based thermoelectric leg. The Bi—Te based thermoelectric leg may be a sintered material composed of plate-shaped alloy powder. The grain size of the plate-shaped alloy powder forming the sintered material may be 90 μm to 180 μm.

The disclosure is not limited to the foregoing embodiments but various modifications or changes may rather be made thereto without departing from the spirit and scope of the disclosure.

### BRIEF DESCRIPTION OF DRAWINGS

These and/or other aspects of the disclosure will become apparent and more readily appreciated from the following description of embodiments, taken in conjunction with the accompanying drawings listed below.

FIG. 1 is a perspective view illustrating the structure of a thermoelectric element according to an embodiment of the disclosure.

FIG. 2 is a view schematically illustrating a forming process of an N-type thermoelectric element according to an embodiment of the disclosure.

FIGS. 3A to 3C are views illustrating a device for a secondary crushing process in a forming process of an N-type thermoelectric element according to an embodiment of the disclosure.

FIG. 4 is a flowchart illustrating a forming process of an N-type thermoelectric element according to an embodiment of the disclosure.

FIG. 5 is a view illustrating alloy pieces after primary crushing in a forming process of an N-type thermoelectric element according to an embodiment of the disclosure.

FIG. 6 is a view illustrating alloy powder after secondary crushing in a forming process of an N-type thermoelectric element according to an embodiment of the disclosure.

FIG. 7 is a view illustrating a structure in which plate-shaped alloy powder is formed in a forming process of an N-type thermoelectric element according to an embodiment of the disclosure.

FIG. 8A is an enlarged view illustrating a portion of a sintered material that has undergone a sintering process after crushing according to an embodiment of the disclosure.

FIG. 8B is a view illustrating the shape and thermal conductivity of alloy powder crushed by equipment according to an embodiment of the disclosure.

FIG. 9 is a view illustrating power factor (PF) according to the size of alloy powder according to an embodiment of the disclosure.

FIG. 10A is a view illustrating the shape and electron backscatter diffraction (EBSD) of powder by a general mechanical alloying method.

FIG. 10B is a view illustrating the shape and electron backscatter diffraction (EBSD) of powder by multiple crushing according to an embodiment of the disclosure.

FIG. 11 is a perspective view illustrating a refrigerator according to an embodiment of the disclosure.

### MODE FOR THE INVENTION

It should be appreciated that various embodiments of the disclosure and the terms used therein are not intended to limit the technological features set forth herein to particular embodiments and include various changes, equivalents, or replacements for a corresponding embodiment.

With regard to the description of the drawings, similar reference numerals may be used to refer to similar or related elements.

It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases.

In the disclosure, the term “and/or” may denote a combination(s) of a plurality of related components as listed or any of the components.

In the disclosure, such terms as “1st” and “2nd,” or “first” and “second” may be used to simply distinguish a corresponding component from another, and does not limit the components in other aspect (e.g., importance or order).

In the disclosure, the terms ‘front surface,’ ‘rear surface,’ ‘upper surface,’ ‘side surface,’ ‘left side,’ ‘right side,’ ‘upper portion,’ and ‘lower portion’ are defined with respect to the drawings, and the shape and position of each component are not limited by the terms.

It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

It will be further understood that the terms “comprise” and/or “have,” as used herein, specify the presence of stated features, integers, steps, operations, elements, and/or components, but do not preclude the presence or addition of one or more other features, integers, steps, operations, elements, components, and/or groups thereof.

It will be understood that when a component is referred to as “connected to,” “coupled to”, “supported on,” or “contacting” another component, the components may be connected to, coupled to, supported on, or contact each other directly or via a third component.

Throughout the specification, when one component is positioned “on” another component, the first component may be positioned directly on the second component, or other component(s) may be positioned between the first and second component.

The refrigerator according to an embodiment may include a main body.

The “main body” may include an inner case, an outer case disposed outside the inner case, and an insulator provided between the inner case and the outer case.

The “inner case” may include at least one of a case, a plate, a panel, or a liner forming a storage compartment. The inner case may be formed as a single body or may be formed by assembling a plurality of plates. The “outer case” may form the outer appearance of the main body and may be coupled to an outer side of the inner case so that the insulator is disposed between the inner case and the outer case.

The “insulator” may insulate the inside of the storage compartment and the outside of the storage compartment so that the temperature inside the storage compartment is maintained at a set appropriate temperature without being affected by the environment outside the storage compartment. According to an embodiment, the insulator may include a foam insulator. The foam insulator may be formed by injecting and foaming a urethane foam formed by mixing polyurethane and a foaming agent between the inner case and the outer case.

According to an embodiment, the insulator may further include a vacuum insulator in addition to the foam insulator, or the insulator may be composed of only a vacuum insulator instead of the foam insulator. The vacuum insulation material may include a core material and an outer cover material that accommodates the core material and seals the inside at a pressure close to vacuum or vacuum. However, the insulator is not limited to the foam insulator or the vacuum insulator, and may include various materials that may be used for insulation.

The “storage compartment” may include a space limited by the inner case. The storage compartment may further include an inner case that limits a space corresponding to the storage compartment. Various items such as food, medicine, cosmetics, etc. may be stored in the storage compartment, and the storage compartment may be formed so that at least one side thereof is opened to take in and out the items.

The refrigerator may include one or more storage compartments. In case that two or more storage compartments are formed in the refrigerator, each storage compartment may have a different use and may be maintained at a different temperature. To that end, each storage compartment may be partitioned from each other by a partition wall including an insulator.

The storage compartment may be provided to be maintained in an appropriate temperature range according to the use, and may include a “refrigerating compartment”, a “freezing compartment”, or an “adjustable-temperature compartment” divided by the use and/or temperature range thereof. The refrigerating compartment may be maintained at a temperature suitable for refrigerating and storing items, and the freezing compartment may be maintained at a temperature suitable for freezing and storing items. The term “refrigerating” may mean cooling the item to the extent that the item is not frozen, and for example, the refrigerating compartment may be maintained in the range of 0 degrees Celsius to 7 degrees Celsius. The term “freezing” may mean cooling the item to freeze or remain frozen, and for example, the freezing compartment may be maintained in the range of minus 20 degrees Celsius to minus 1 degree Celsius. The adjustable-temperature compartment may be used as any one of the refrigerating compartment or the freezing compartment regardless of the user's selection.

The storage compartment may be referred to as a “vegetable compartment”, a “fresh compartment”, a “cooling compartment”, an “ice-making compartment”, and the like, in addition to the names “refrigerating compartment”, “freezing compartment”, and “adjustable-temperature compartment”, and the terms “refrigerating compartment”, “freezing compartment”, and “adjustable-temperature compartment” used below should be understood to collectively mean storage compartments having their respective corresponding uses and temperature ranges.

According to an embodiment, the refrigerator may include at least one door configured to open and close one open side of the storage compartment. The door may be provided to open and close each of one or more storage compartments, or one door may be provided to open and close a plurality of storage compartments. The door may be rotatably or slidably installed on the front surface of the main body.

The “door” may be configured to seal the storage compartment in case that the door is closed. Like the main body, the door may include an insulator to insulate the storage compartment in case that the door is closed.

According to an embodiment, the door may include a door outer plate forming a front surface of the door, a door inner plate forming a rear surface of the door and facing the storage compartment, an upper cap, a lower cap, and a door insulator provided thereinside.

A gasket may be provided on the edge of the door inner plate to seal the storage compartment by being in close contact with the front surface of the main body in case that the door is closed. The door inner plate may include a dyke protruding rearward to mount a door basket capable of storing an object.

According to an embodiment, the door may include a door body and a front panel detachably coupled to a front side of the door body and forming a front surface of the door. The door body may include a door outer plate forming a front surface of the door body, a door inner plate forming a rear surface of the door body and facing the storage compartment, an upper cap, a lower cap, and a door insulator provided thereinside.

The refrigerator may be classified into a French door type, a side-by-side type, a bottom mounted freezer (BMF), a top mounted freezer (TMF), or a one-door refrigerator according to the arrangement of the door and the storage compartment.

According to an embodiment, the refrigerator may include a cold air supply device configured to supply cold air to the storage compartment.

The “cold air supply device” may include a machine, an instrument, an electronic device, and/or a system combining the machine, the instrument, and the electronic device capable of generating cold air and guiding the cold air to cool the storage compartment.

According to an embodiment, the cold air supply device may generate cold air through a refrigerating cycle including processes of compressing, condensing, expanding, and evaporating the refrigerant. To that end, the cold air supply device may include a refrigerating cycle device having a compressor, a condenser, an expansion device, and an evaporator capable of driving the refrigerating cycle. According to an embodiment, the cold air supply device may include a semiconductor such as a thermoelectric element. The thermoelectric element may cool the storage compartment by heating and cooling through the Peltier effect.

According to an embodiment, the refrigerator may include a machine room in which at least some components belonging to the cold air supply device are arranged.

The “machine room” may be provided to be partitioned and insulated from the storage compartment to prevent heat generated from components disposed in the machine room from being transferred to the storage compartment. The inside of the machine room may be configured to communicate with the outside of the main body to dissipate heat from components disposed inside the machine room.

According to an embodiment, the refrigerator may include a dispenser provided on the door to provide water and/or ice. The dispenser may be provided on the door to be accessed by the user without opening the door.

According to an embodiment, the refrigerator may include an ice maker provided to generate ice. The ice maker may include an ice-making tray storing water, an ice maker separating ice from the ice-making tray, and an ice bucket storing ice generated in the ice-making tray.

According to an embodiment, the refrigerator may include a controller for controlling the refrigerator.

The “controller” may include a memory storing or recording a program and/or data for controlling the refrigerator, and a processor outputting a control signal for controlling the cold air supply device according to the program and/or data stored in the memory.

The memory stores or records various information, data, instructions, programs, etc. necessary for the operation of the refrigerator. The memory may store temporary data generated while generating a control signal for controlling components included in the refrigerator. The memory may include at least one of a volatile memory and a non-volatile memory or a combination thereof.

The processor controls the overall operation of the refrigerator. The processor may control the components of the refrigerator by executing a program stored in the memory. The processor may include a separate NPU that performs the operation of the artificial intelligence model. The processor may include a central processing unit, a graphics-only processor (GPU), and the like. The processor may generate a control signal for controlling the operation of the cold air supply device. For example, the processor may receive temperature information about the storage compartment from the temperature sensor, and generate a cooling control signal for controlling the operation of the cold air supply device based on the temperature information about the storage compartment.

Further, the processor may process the user input received from the user interface according to the program and/or data stored/stored in the memory, and control the operation of the user interface. The user interface may be provided using an input interface and an output interface. The processor may receive a user input from the user interface. Further, the processor may transfer a display control signal and image data for displaying an image on the user interface to the user interface in response to the user input.

The processor and the memory may be provided integrally or separately. The processor may include one or more processors. For example, the processor may include a main processor and at least one sub-processor. The memory may include one or more memories.

The refrigerator may include a processor and a memory controlling all components included in the refrigerator, and a plurality of processors and a plurality of memories individually controlling the components of the refrigerator. For example, the refrigerator may include a processor and a memory controlling the operation of the cold air supply device according to the output of the temperature sensor. Further, the refrigerator may include a separate processor and a separate memory controlling the operation of the user interface according to a user input.

The communication module may communicate with an external device such as a server, a mobile device, another home appliance, or the like through an access point (AP). The AP may connect the local area network (LAN) to which the refrigerator or the user equipment is connected to the wide area network (WAN) to which the server is connected. The refrigerator or the user device may be connected to the server through the wide area network (WAN).

The input interface may include a key, a touch screen, a microphone, and the like. The input interface may receive a user input and transfer the user input to the processor.

The output interface may include a display, a speaker, and the like. The output interface may output various notifications, messages, information, and the like generated by the processor.

Hereinafter, embodiments of the disclosure are described in detail with reference to the accompanying drawings.

Meanwhile, the terms “upper”, “lower”, “front”, and “rear” used in the following description are defined with respect to the drawings, and the shape and position of each component are not limited by these terms. For example, the terms “front” and “rear” below may mean the front and rear, respectively, of the refrigerator in the X direction with respect to the drawings. The terms “upper” and “lower” below may mean upper and lower, respectively, in the Z direction of the refrigerator with respect to the drawings. The terms “left” and “right” below may mean the left and right, respectively, in the Y direction of the refrigerator with respect to the drawings.

Hereinafter, a thermoelectric semiconductor (hereinafter, thermoelectric element) used in a cold air supply device is described. The thermoelectric element is described as a semiconductor for cooling a storage compartment of a refrigerator, but is not limited thereto, and may be easily modified and applied to various home appliances in which thermoelectric elements are utilized, such as an air purifying humidifier, a robot cleaner, a cooking device, or a washer.

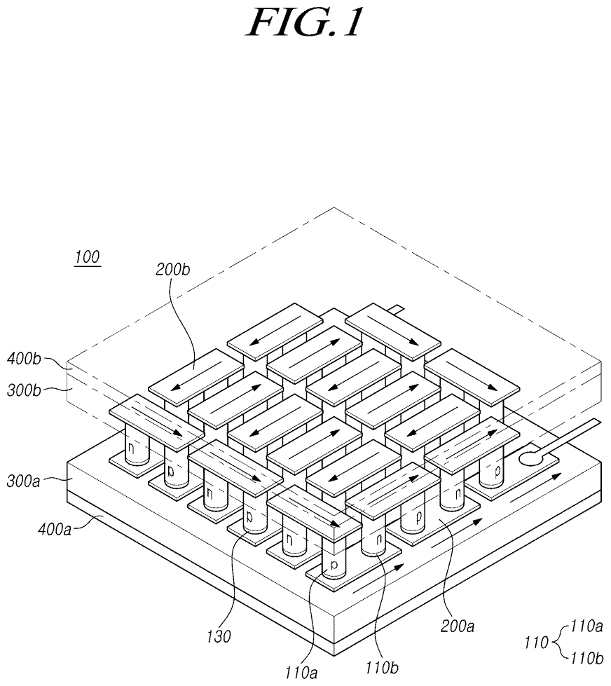

FIG. 1 is a perspective view illustrating the structure of a thermoelectric element 100 according to an embodiment of the disclosure.

Referring to FIG. 1, a thermoelectric element 100 may include a plurality of thermoelectric legs 110 (e.g., thermoelectric materials), electrodes 200a and 200b, substrates 300a and 300b, a heat dissipation plate 400a, and/or a heat absorption plate 400b.

According to an embodiment, the thermoelectric element 100 may include a first substrate 300a, a second substrate 300b disposed in parallel with the first substrate 300a, a first electrode 200a disposed on the first substrate 300a, a second electrode 200b disposed on the second substrate 300b, and a thermoelectric leg 110 disposed between the first electrode 200a and the second electrode 200b. The first electrode 200a and the second electrode 200b may be disposed between the first substrate 300a and the second substrate 300b. The first electrode 200a and the second electrode 200b form a designated pattern, and a plurality of each electrode may be disposed.

According to an embodiment, the first substrate 300a and the second substrate 300b may each cause a heat generation reaction or a heat absorption reaction in case that power is applied to the thermoelectric element 100. The first substrate 300a and the second substrate 300b may each be formed in a plate shape and formed of various materials. According to an embodiment, the first substrate 300a and/or the second substrate 300b may be formed of a non-conductive material such as ceramic or insulating resin. For example, the first substrate 300a and/or the second substrate 300b may be formed of one of Al₂O₃, AlN, SiC, or ZrO₂ or a combination thereof. According to an embodiment, the first substrate 300a and/or the second substrate 300b may be a substrate of a conductive material (e.g., metal) capable of conducting electricity. For example, the first substrate 300a and/or the second substrate 300b may be formed of one of aluminum (Al), zinc (Zn), copper (Cu), nickel (Ni), or cobalt (Co) or a combination thereof. In case that the first substrate 300a and/or the second substrate 300b are formed of a conductive material, an insulation layer may be disposed between the substrates 300a, 300b and the electrodes 200a, 200b so as not to be electrically connected to the electrodes 200a, 200b.

According to an embodiment, the first substrate 300a and the second substrate 300b are disposed to face each other, a plurality of first electrodes 200a are disposed on an inner surface of the first substrate 300a, and a plurality of second electrodes 200b may be disposed on an inner surface of the second substrate 300b. The first electrode 200a and the second electrode 200b are disposed so that at least portions thereof face each other, and may be formed of a conductive material (e.g., metallic material) through which current may move. For example, the first electrode 200a and/or the second electrode 200b may be one of aluminum (Al), zinc (Zn), copper (Cu), nickel (Ni), cobalt (Co), nickel (Ni), gold (Au), silver (Ag), copper (Cu), or titanium (Ti) or a combination thereof. The first electrode 200a and the second electrode 200b may be formed of the same type of material or different types of materials.

According to an embodiment, the first electrode 200a and/or the second electrode 200b may form a pattern of a designated shape. For example, the plurality of first electrodes 200a may be disposed at designated intervals on the first substrate 300a. For example, the plurality of second electrodes 200b may be disposed at designated intervals on the second substrate 300b. The arrangement of the plurality of first electrodes 200a and the plurality of second electrodes 200b is not limited to the pattern disclosed in FIG. 1, and may be modified to various patterns capable of easily transmitting current.

According to an embodiment, the plurality of thermoelectric legs 110 may each be disposed between the first electrode 200a and the second electrode 200b. Each thermoelectric leg 110 may have one side connected to the first electrode 200a and the other side connected to the second electrode 200b.

According to an embodiment, the plurality of thermoelectric legs 110 may include a plurality of P-type thermoelectric legs 110a and a plurality of N-type thermoelectric legs 110b. The P-type thermoelectric legs 110a and the N-type thermoelectric legs 110b may be alternately arranged in one direction. For example, the plurality of thermoelectric legs 110 may be arranged in an array such as M rows×N columns (where M and N are natural numbers) on the electrodes 200a and 200b or the substrates 300a and 300b. For example, one row (or column) of the plurality of thermoelectric legs 110 may be arranged in the order of a P-type thermoelectric leg 110a, an N-type thermoelectric leg 110b, a P-type thermoelectric leg 110a, and an N-type thermoelectric leg 110b.

According to an embodiment, the P-type thermoelectric legs 110a adjacent to each other in one direction may have upper and lower surfaces electrically connected in series with the first electrode 200a and the second electrode 200b. According to an embodiment, N-type thermoelectric legs 110b neighboring in one direction may have upper and lower surfaces electrically connected in series with a first electrode 200a and a second electrode 200b.

According to an embodiment, thermoelectric legs 110 (e.g., P-type thermoelectric legs 110a and N-type thermoelectric legs 110b) may include a diffusion barrier layer (130). The diffusion barrier layer (130) may be disposed on the upper side and/or lower side of thermoelectric leg 110. The diffusion barrier layers (130) disposed on different sides may be composed of different materials. The diffusion barrier layer (130) may be formed on the thermoelectric leg 110 by a dry deposition process.

According to an embodiment, the first electrode 200a and the second electrode 200b of thermoelectric element 100 may be electrically connected to a power supply source. In case that a DC voltage is applied from the outside, holes of the P-type thermoelectric leg 110a and electrons of the N-type thermoelectric leg 110b move, so that heat generation and heat absorption may occur at two opposite ends of thermoelectric leg 110.

According to an embodiment, at least one of the first electrode 200a and the second electrode 200b of thermoelectric element 100 may be exposed to a heat supply source. In case that heat is supplied by an external heat supply source, electrons and holes move to generate a current flow in thermoelectric element, thereby causing power generation.

According to an embodiment, the heat dissipation plate 400a and the heat absorption plate 400b are disposed to face each other and may form one side and the other side of thermoelectric element 100. The heat dissipation plate 400a may be disposed on a first substrate 300a, and the heat absorption plate 400b may be disposed on a second substrate 300b. Referring to FIG. 1, the heat dissipation plate 400a may form the lower side of thermoelectric element 100 and the heat absorption plate 400b may form the upper side of thermoelectric element 100. The heat absorption plate 400b may be disposed on the cold side of thermoelectric element 100, and the heat dissipation plate 400a may be disposed on the hot side to absorb and dissipate heat, respectively.

According to an embodiment, the heat dissipation plate 400a is a portion where thermoelectric element 100 dissipates heat, and heat may be dissipated to the outside by the heat dissipation plate 400a. The heat dissipation plate 400a may be positioned on the higher temperature side to dissipate heat to the outside. The heat dissipation plate 400a lowers the temperature of thermoelectric element 100 and prevents overheating, thereby providing efficient thermoelectric conversion of thermoelectric element 100 and maintaining thermal performance.

According to an embodiment, the heat absorption plate 400b is a portion where thermoelectric element 100 absorbs heat, and heat may be absorbed from the outside by the heat absorption plate 400b. The heat absorption plate 400b may be positioned on the lower temperature side to absorb heat. This may allow thermoelectric element 100 to execute a process of absorbing heat and converting it to electrical energy. The heat absorption plate 400b may quickly absorb heat and transfer it to the inside of thermoelectric element 100.

Hereinafter, the forming process and structure of an N-type thermoelectric element 100a is described in detail.

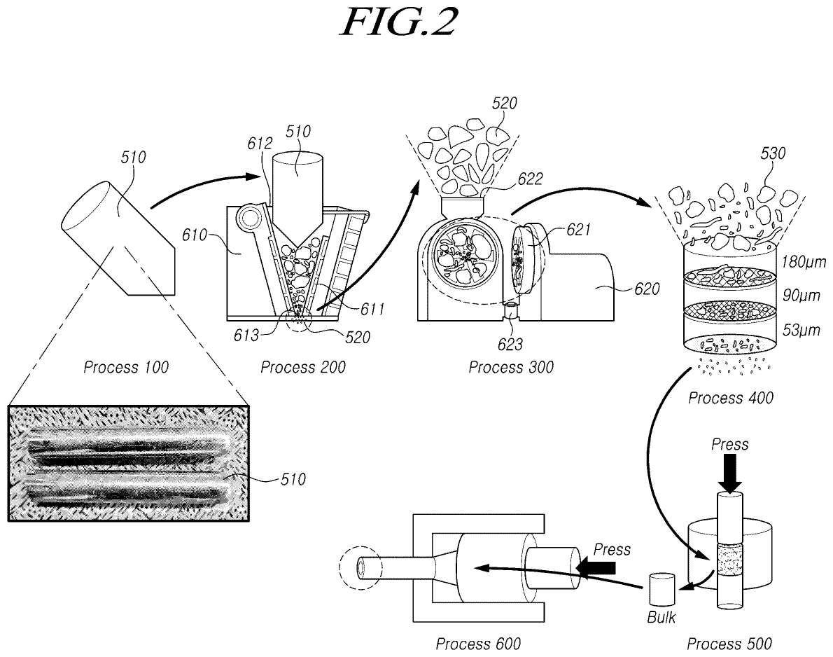

FIG. 2 is a view schematically illustrating a forming process of an N-type thermoelectric element according to an embodiment of the disclosure.

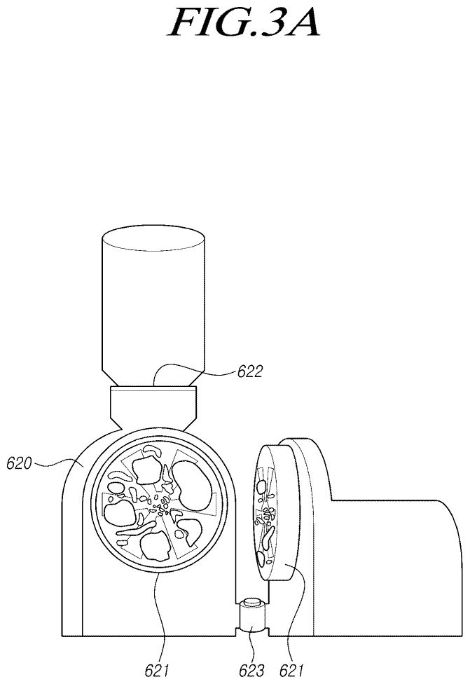

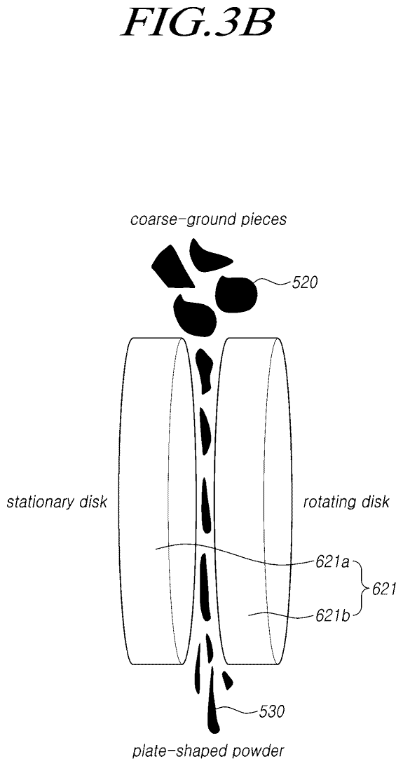

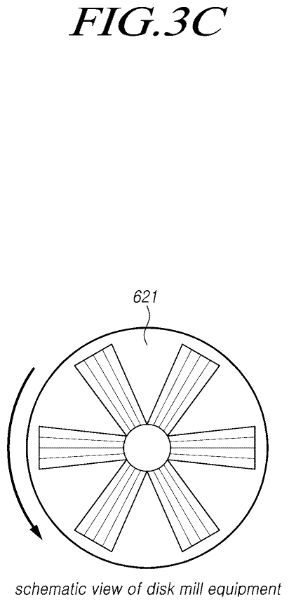

FIGS. 3A to 3C are views illustrating a device for a secondary crushing process in a forming process of an N-type thermoelectric element according to an embodiment of the disclosure.

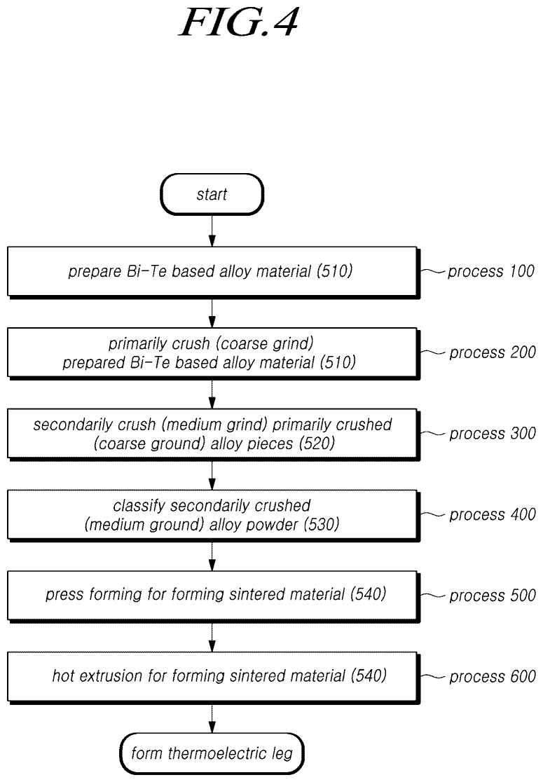

FIG. 4 is a flowchart illustrating a forming process of an N-type thermoelectric element according to an embodiment of the disclosure.

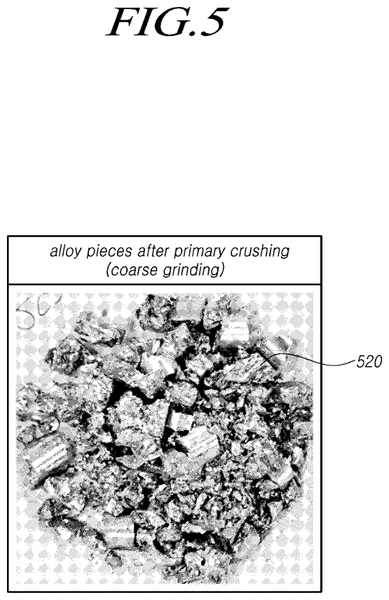

FIG. 5 is a view illustrating alloy pieces after primary crushing in a forming process of an N-type thermoelectric element according to an embodiment of the disclosure.

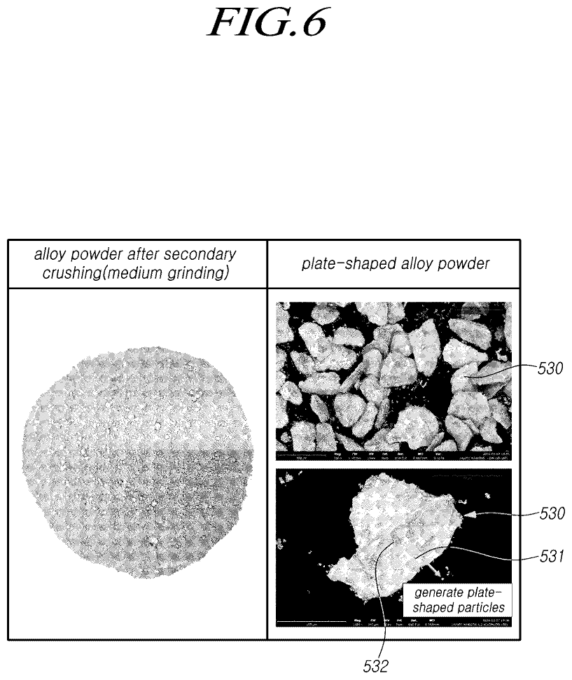

FIG. 6 is a view illustrating alloy powder after secondary crushing in a forming process of an N-type thermoelectric element according to an embodiment of the disclosure.

According to an embodiment, a thermoelectric element (e.g., thermoelectric element 100 of FIG. 1) includes a thermoelectric leg 110 (e.g., Peltier leg), and thermoelectric leg 110 may be formed through a plurality of processes. Hereinafter, the forming process of the thermoelectric leg 110 is an example of an N-type thermoelectric element forming process.

The configuration of thermoelectric leg 110 of FIGS. 2 to 6 may be identical in whole or part to the configuration of thermoelectric leg 110 of FIG. 1.

The embodiments of FIGS. 2 to 6 may be selectively combined with the embodiments of FIGS. 1 and 7 to 11.

According to an embodiment, a thermoelectric leg 110 is a thermoelectric semiconductor and may be a thermoelectric material that generates a temperature difference at two opposite ends in case that electricity is applied, or a thermoelectric material that generates electricity by a temperature difference generated at two opposite ends. The thermoelectric leg 110 may be designed in a cylindrical shape or a rectangular pillar shape. The thermoelectric leg 110 may be the N-type thermoelectric leg 110b of FIG. 1.

According to an embodiment, the material of the thermoelectric leg 110 (or materials before being formed into the thermoelectric leg 110 (e.g., alloy material 510, alloy pieces 520, alloy powder 530)) may include at least one element selected from the group consisting of transition metals, rare earth elements, Group 13 elements, Group 14 elements, Group 15 elements, or Group 16 elements. For example, the rare earth elements include elements such as Y, Ce, and La, and the transition metal may be one of Ti, Zr, Hf, V, Nb, Ta, Cr, Mo, W, Mn, Fe, Co, Ni, Cu, Zn, Ag, or Re, and an example of the Group 13 element may be one of B, Al, Ga, or In, and an example of the Group 14 element may be one of C, Si, Ge, Sn, or Pb, and an example of the Group 15 element may be one of P, As, Sb, or Bi, and an example of the Group 16 element may be one of S, Se, or Te.

According to an embodiment, the thermoelectric leg 110 (or materials before being formed into the thermoelectric leg 110 (e.g., alloy material 510, alloy pieces 520, alloy powder 530)) may be composed of a composition including at least two or more of bismuth (Bi), tellurium (Te), selenium (Se), cobalt (Co), antimony (Sb), indium (In), or cerium (Ce). For example, the thermoelectric leg 110 may be at least one of Bi—Te-based, Co—Sb-based, Pb—Te-based, Ge—Tb-based, Si—Ge-based, Sb—Te-based, Sm—Co-based, transition metal silicide-based, Skutterudite-based, Silicide-based, or Half Heusler. For example, the thermoelectric leg 110 may include a (Bi,Sb)₂(Te,Se)₃-based thermoelectric semiconductor in which Sb and Se are used as dopants as a Bi—Te-based thermoelectric semiconductor. For example, the thermoelectric leg 110 may include a CoSb₃-based thermoelectric semiconductor as a Co—Sb-based thermoelectric semiconductor. For example, the thermoelectric leg 110 may include AgSbTe₂ or CuSbTe₂ as a Sb—Te-based thermoelectric semiconductor. For example, the thermoelectric leg 110 may include PbTe or (PbTe)mAgSbTe₂ as a Pb—Te-based thermoelectric semiconductor. Hereinafter, the description is based on the premise that the thermoelectric leg 110 is composed of a Bi—Te based (e.g., Bi₂—Te₃ based) thermoelectric material.

Hereinafter, the forming process of the thermoelectric leg 110 is described in detail. The materials before forming thermoelectric leg 110 may be named as alloy material 510, alloy piece 520, and alloy powder 530 according to size.

According to process 100, a process of preparing an alloy material 510 may be performed. According to an embodiment, the alloy material 510 may be a Peltier material (or Peltier element) including a Bi—Te based (e.g., Bi₂—Te₃ based) material. For example, the Peltier material is a main component used in a thermoelectric module utilizing the Peltier effect, and the Peltier effect is a phenomenon in which heat is absorbed or released in case that current flows between two types of semiconductors (e.g., P-type and N-type semiconductors), through which a temperature difference may be created.

According to an embodiment, the alloy material 510 may be named as an alloy ingot or alloy lump. The alloy material 510 may have a lump shape of a designated size as illustrated in the drawing of FIG. 2 in a state before main processing. For example, the alloy material 510 may be manufactured in a cylindrical shape in a state before crushing processing.

According to an embodiment, the alloy material 510 may be identical or similar to the material of the thermoelectric leg 110 described above. The alloy material 510 is based on bismuth (Bi) and tellurium (Te), and may be a material to which selenium (Se) is added. The selenium (Se) may be added in small amounts to Bi—Te series thermoelectric alloys. The selenium (Se) may be included in a range of 0.1 to 0.5 mol. % relative to the total mol. % of the alloy material 510. The selenium (Se) may enhance electrical conductivity and/or thermoelectric performance in Bi—Te series thermoelectric alloys.

According to an embodiment, the alloy material 510 is an ingot or lump for crushing to facilitate the primary crushing process and may be manufactured in a shape similar to a cylinder. According to an embodiment, the alloy material 510 may be processed through a melting and casting process. For example, the processed alloy material 510 may be formed to have a size with a diameter Φ of about 25 mm to 40 mm and a length of about 50 mm to 300 mm. For example, the alloy material 510 may have a length of about 300 mm or less. For example, the alloy material 510 may have a weight of about 200 g or less. For example, the alloy material 510 may have a weight of about 50 g to 200 g. The disclosed size and weight of the alloy material 510 is an example formed to a size that may be easily inserted into the primary crushing equipment 610 and is not limited thereto, and may be design-changed to various sizes considering the primary crushing process.

According to process 200, a primary crushing (coarse grinding or rough grinding) process of the prepared Bi—Te based alloy material 510 may be performed. Process 200 is an initial crushing process among multiple crushing processes for forming the thermoelectric leg 110, and through the primary crushing process, the alloy material 510 may be formed into alloy pieces 520 having a first length L1.

According to an embodiment, the primary crushing process proceeds by crushing the alloy material 510 through primary crushing equipment 610, and the primary crushing equipment 610 may be named as a jaw crusher. The primary crushing equipment 610 may include a plurality of crushing plates (jaws) 611. The primary crushing equipment 610 includes a stationary crushing plate (stationary jaw) and a movable crushing plate (movable jaw), and the two crushing plates 611 may compress the alloy material 510 while closely engaging with each other. For example, the alloy material 510 may be input between the gaps while the gap between the two crushing plates 611 is set to about 1 mm to 5 mm. The crushing plates 611 may be manufactured from cemented carbide. If the alloy material 510 enters the input port 612 of the primary crushing equipment 610, the stationary crushing plate and the movable crushing plate move up/down or forward/backward to compress and crush from one end of the alloy material 510. The alloy material 510 moving according to the up/down or forward/backward movement may be gradually crushed into smaller pieces. The crushed material (e.g., alloy pieces 520) is discharged through the discharge port 613 and may be separated into pieces of uniform size.

According to an embodiment, the alloy pieces 520 are pieces crushed to a smaller size than the alloy material 510 to facilitate the secondary crushing process and may be prepared as pieces of generally uniform size through the primary crushing equipment 610. FIG. 5 illustrates the alloy pieces after primary crushing. For example, each of the alloy pieces 520 may have a length (e.g., first length L1) of about 30 mm or less on average. For example, each of the alloy pieces 520 has an irregular shape but may have, on average, length of about 10 mm to 30 mm, a width of about 10 mm to 30 mm, and a thickness of about 10 mm to 30 mm. The disclosed size of the alloy pieces 520 is an example formed to a size that may be easily inserted into the secondary crushing equipment 620 and is not limited thereto, and may be design-changed to various sizes considering the secondary crushing process.

According to process 300, a secondary crushing (medium grinding) process of the primarily crushed (coarse grinding or rough grinding) alloy pieces 520 may be performed. Process 300 is the final crushing process among the multiple crushing processes for forming the thermoelectric leg 110, and through the secondary crushing process, the alloy pieces 520 may be crushed into alloy powder 530 having a second length L2. The alloy powder 530 that has undergone the secondary crushing process may have a plate shape or flake shape.

According to an embodiment, the secondary crushing process proceeds by crushing work of the alloy pieces 520 inserted into the secondary crushing equipment 620, and the secondary crushing equipment 620 may be named as a disk mill. The secondary crushing equipment 620 may include a plurality of disks 621.

Referring to FIGS. 3A, 3B, and 3C, the secondary crushing equipment 620 may include two rotatable circular disks 621, an input port 622, a discharge port 623, a motor, and/or an adjusting mechanism. In the secondary crushing process, the two parallel disks 621 are disposed facing each other, a first disk 621a out of the disks 621 is in a stationary state, a second disk 621b provides rotational motion, and the alloy pieces 520 may be input between the disks. The alloy pieces 520 may be crushed by receiving friction and impact between the rotating second disk 621b and the fixed first disk 621a. As the surfaces of the disks 621 usually include a sawtooth shape or rough surface, crushing may be efficiently performed while the alloy pieces 520 contact between the disks 621. The disks 621 are formed of steel or alloy to provide excellent durability and may be formed of a material resistant to wear.

According to an embodiment, in the secondary crushing process, the gap between the disks 621 for crushing the alloy pieces 520 may be set to 0.1 mm to 10 mm. The set gap may be variously adjusted by the operator to obtain an enhanced thermoelectric leg 110, and the adjustment may be made through the adjusting mechanism. According to an embodiment, in the secondary crushing process, the rotation speed of the second disk 621 may be set to about 440 RPM.

According to an embodiment, in the secondary crushing process, the alloy pieces 520 input through the input port 622 are compressed and crushed while passing between the disks 621 to change (e.g., crush) into plate-shaped alloy powder 530, and the changed plate-shaped alloy powder 530 may be discharged through the discharge port 623. The material crushed through the secondary crushing equipment 620 (e.g., plate-shaped alloy powder 530) may be crushed into pieces of uniform size and separated through the discharge port 623. The alloy pieces 520 input through the input port 622 may be about 50 g to 200 g at one time.

According to an embodiment, the alloy powder 530 is powder crushed to a smaller size than the alloy pieces 520 to be easily formed into a sintered material for thermoelectric leg 110, and may be prepared as plate-shaped powders of generally uniform size through the secondary crushing equipment 620. FIG. 6 illustrates the secondarily crushed alloy powder 530. For example, each of the plate-shaped alloy powder 530 may have a length (e.g., second length L2) of about 200 μm or less on average. For example, each of the plate-shaped alloy powder 530 has an irregular shape but may have, on average, a length of about 100 μm to 200 μm, a width of about 100 μm to 150 μm, and a thickness of about 5 μm to 20 μm. The disclosed size of the alloy powder 530 is an example for easily forming the thermoelectric leg 110 through a sintering process and is not limited thereto, and may be design-changed to various sizes considering the efficiency of the thermoelectric leg 110.

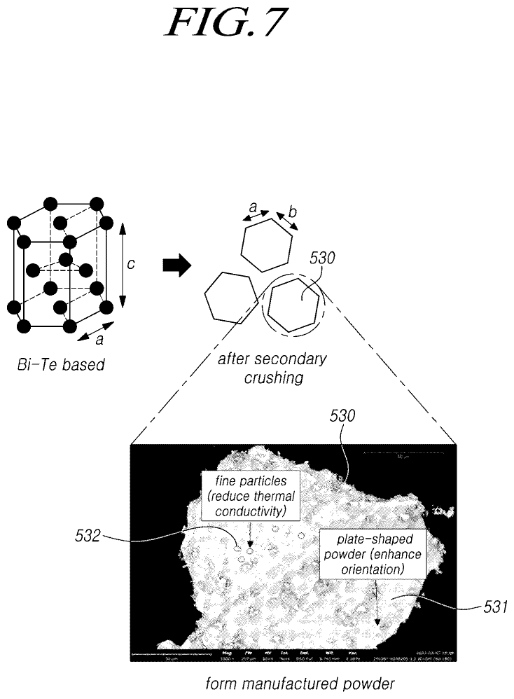

According to an embodiment, referring to FIG. 6, each of the alloy powder 530 may include a plate-shaped particle 531 and a plurality of fine particles 532 at least partially inserted on the plate-shaped particle 531. The alloy powder 530 is formed by passing through the disks 621 of the secondary crushing equipment 620, and the alloy powder 530 formed therethrough may be provided entirely in a plate shape to be advantageous for orientation and electrical conductivity. For example, the disks 621 of the secondary crushing equipment 620 are equipment that may apply shear stress in the horizontal direction and, in case that the alloy pieces 520 having a layered structure are crushed while passing between the disks 621, shear force is applied in the direction of interlayer bonding (e.g., c-axis bonding in FIG. 7) of the layered structure with weak bonding, causing interlayer slip and/or separation, so that a thin plate-shaped structure may be easily formed.

According to process 400, a classification process of the secondarily crushed (medium grinding) alloy powder 530 may be performed. Process 400 is a process of classifying the secondarily crushed alloy powder 530 by size, and the classified alloy powder 530 may use only the alloy powder 530 advantageous for the thermoelectric leg 110 by comparing performance (e.g., electrical conductivity, orientation) according to size.

According to an embodiment, the classification process (e.g., process 400) proceeds by performing classification multiple times (e.g., 3 times) to classify the secondarily crushed alloy powder 530 by size, and the classification may use various classifications such as sieving or centrifugal classification. Hereinafter, sieving is described.

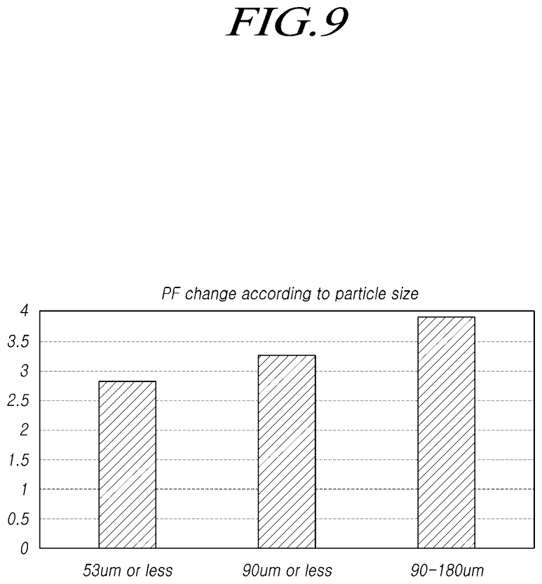

According to an embodiment, the classification process is conducted over a total of 3 times, where in the first classification process, a sieve is used that allows only alloy powder 530 with a length of 180 μm or less to pass through, in the second classification process, a sieve is used that allows only alloy powder 530 with a length of 90 μm or less to pass through, and in the third classification process, a sieve is used that allows only alloy powder 530 with a length of 53 μm or less to pass through. Through the classification process, the alloy powder 530 is classified into alloy powder 530 of about 90 μm to 180 μm, alloy powder 530 of about 53 μm to 90 μm, and alloy powder 530 of about 53 μm or less, and through experiments (e.g., FIG. 9), the alloy powder 530 of about 90 μm to 180 μm with a power factor (PF) of 3.5 or more may be used in the next process (e.g., forming the thermoelectric leg 110).

According to process 500, press forming for forming a sintered material may be performed. The sintering process is a manufacturing method that combines raw materials in an alloy state by applying heat at high temperature to make them into a solid form, and may be a process for sintering the alloy powder 530 of 90 μm to 180 μm to make the thermoelectric leg 110.

According to an embodiment, press forming may be performed through processes of preparing the alloy powder 530 (powder preparation), injecting the alloy powder 530 into a die (powder filling into die) and compression, and then extracting the product if forming is complete (formed product extraction). The alloy powder 530 for preparation may have a size of about 90 μm to 180 μm. In case of injecting the alloy powder 530 into the die, foreign objects or air bubbles should not enter inside, and during compression, high pressure (e.g., 100 MPa or more) is used, and through this process, the alloy powder 530 may be finely aggregated and density may increase.

According to an embodiment, the alloy powder 530 compressed by press forming may have low mechanical strength and be brittle, so a high-temperature treatment process may proceed immediately.

According to process 600, hot extrusion for forming a sintered material may be performed. Through the hot extrusion, after press forming, the alloy powder 530 with insufficient mechanical strength may be strongly bonded (sintered). The sintered alloy is smaller in size than the alloy powder 530, and the sintered powders may be in a state bonded with orientation.

According to an embodiment, the hot extrusion may prepare materials to be used for extrusion (e.g., in billet or preform form) and heat them to a designated temperature. The heating is to facilitate deformation of the material, and the temperature varies according to the type of material, but may be about 300° C. to 500° C. After heating, the material is inserted into extrusion equipment, strong pressure is applied to push the material through a die, and the material may have a constant diameter (or width) and continuous form. Thereafter, the extruded material may form the thermoelectric leg 110 through cooling and post-processing. Cooling may be selectively performed by natural cooling or forced cooling. Post-processing may include cutting, surface treatment, and machining. A sintered material 540 (sintered alloy, sintered powders, or crystal grains) and (or) the thermoelectric leg 110 may be formed through cutting and surface treatment multiple times to a size to be used in the thermoelectric element 100.

According to an embodiment, the thermoelectric leg 110 that has undergone the sintering process and post-processing may have multiple layers such as a diffusion barrier layer disposed on two opposite sides of the thermoelectric leg 110 for performance enhancement.

FIG. 7 is a view illustrating a structure in which plate-shaped alloy powder is formed in a forming process of an N-type thermoelectric element according to an embodiment of the disclosure.

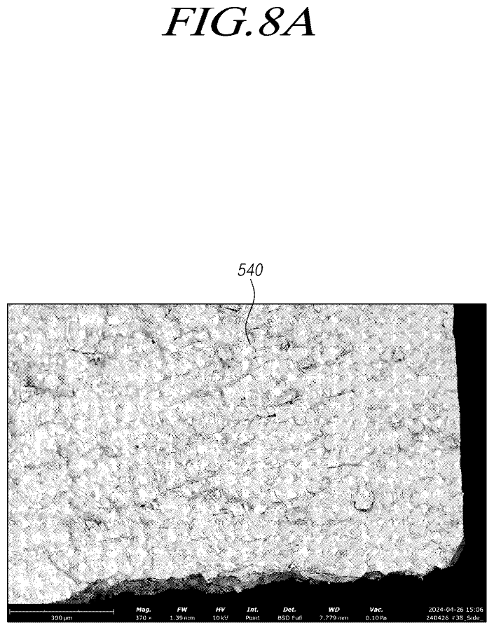

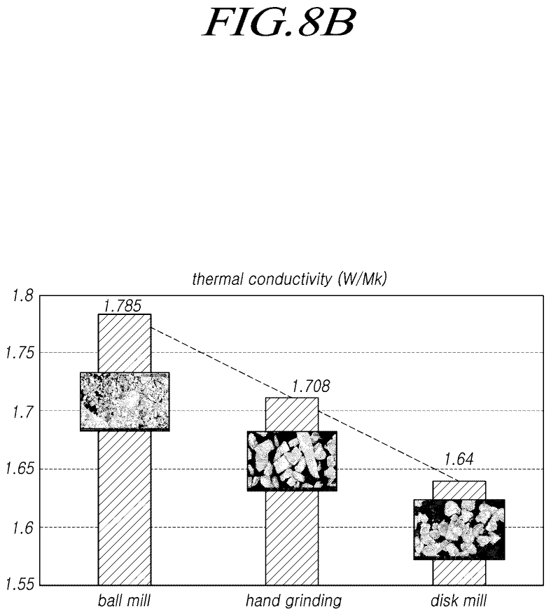

FIG. 8A is an enlarged view illustrating a portion of a sintered material that has undergone a sintering process after crushing according to an embodiment of the disclosure.

FIG. 8B is a view illustrating the shape and thermal conductivity of alloy powder crushed by equipment according to an embodiment of the disclosure.

According to an embodiment, a thermoelectric element (e.g., thermoelectric element 100 of FIG. 1) includes a thermoelectric leg 110 (e.g., Peltier leg) (e.g., the thermoelectric leg 110 of FIG. 1), and thermoelectric leg 110 may be formed through a plurality of processes. Hereinafter, the forming process of the thermoelectric leg 110 is an example of an N-type thermoelectric element forming process.

The configuration of the thermoelectric leg 110 of FIGS. 7 to 8B may be identical in whole or part to the configuration of the thermoelectric leg 110 of FIG. 1.

The embodiments of FIGS. 7 to 8B may be selectively combined with the embodiments of FIGS. 1 to 6 and FIGS. 9 to 11.

According to an embodiment, the forming process of the thermoelectric leg 110 may include a primary crushing (coarse grinding or rough grinding) process of a Bi—Te based alloy material 510 (e.g., process 200 of FIG. 4), a secondary crushing (medium grinding) process of the primarily crushed (coarse grinding or rough grinding) alloy pieces (e.g., process 300 of FIG. 4), and a sintering process (e.g., process 500 and process 600 of FIG. 4).

According to an embodiment, the crushing process (e.g., primary crushing process, secondary crushing process) may enhance thermoelectric performance (e.g., electrical conductivity, orientation) of the thermoelectric leg 110 by utilizing the inherent characteristics of the HCP crystal structure of the Bi—Te based material. Generally, a Bi—Te based thermoelectric material with a layered structure has weak interlayer bonding or is bonded only by van der Waals forces, so the bonding may be easily broken in case that force is applied in the vertical direction (e.g., c-axis). For example, in a Bi—Te based thermoelectric material, the c-axis direction has low mechanical strength and is weak, so it is more likely to break more easily than the a-axis or b-axis direction, so that in case of designing thermoelectric materials, it is necessary to adjust orientation considering structural stability (e.g., considering mechanical weakness in the c-axis direction).

According to an embodiment, in case that the alloy pieces 520 are crushed into plate-shaped alloy powder 530 using equipment that may apply shear stress to a Bi—Te based thermoelectric material with a layered structure (e.g., the secondary crushing equipment 620 of FIGS. 2 and 3), it may be manufactured as a thermoelectric material with structural stability and enhanced orientation. For example, the alloy pieces 520 input to pass between the rotating disks 621 of the secondary crushing equipment 620 may be crushed into thin plate-shaped alloy powder 530 as interlayer separation easily occurs due to weak c-axis bonding due to the characteristics of the layered structure. The plate-shaped alloy powder 530 generated through the shear stress of this secondary crushing equipment 620 may provide a structure that is easy to stack with directionality (e.g., orientation) in a specific direction, as it is present in a state where only strong bonding in the a-axis and b-axis directions is maintained.

The first view of FIG. 7 illustrates a structure where bonding in the c-axis direction according to the HCP crystal structure is weak, and through multiple crushing processes, as illustrated in the second view of FIG. 7, it may be identified that the alloy powder 530 in a state where only strong bonding in the a-axis and b-axis directions is maintained is schematically shown. In case that the alloy powder 530 undergoes a sintering process (press and hot extrusion), it may form a sintered material 540 (e.g., the thermoelectric leg 110) with excellent orientation.

According to an embodiment, the performance of thermoelectric element may be significantly affected by the orientation of the sintered material 540 (sintered alloy). For example, in a Bi—Te based thermoelectric material, the (0001) plane (e.g., basal plane or plane perpendicular to the c-axis) is the most important plane for thermoelectric performance and may affect mechanical, electrical, and thermoelectric properties such as electrical conductivity, thermal conductivity, and/or Seebeck coefficient. In other words, if the crystal structure is aligned in a predetermined direction (e.g., having orientation), the path through which electrons flow becomes clear, enhancing electrical conductivity. For example, a crystal structure with orientation may facilitate the flow of electrons by reducing defects or irregular paths that hinder electron movement.

Referring to FIG. 8A, it may be identified that the alloy powder 530 illustrates a sintered material 540 (e.g., the thermoelectric leg 110) through a sintering process (press and hot extrusion). It may be identified that the sintered material 540 of FIG. 8A has orientation in the crystal grains (e.g., sintered powders). For example, the sintered material 540 is a sintered component of the plate-shaped alloy powder 530 that maintains only strong bonding in the a-axis and b-axis directions through multiple crushing processes, and the crystal grains of the sintered material 540 form a structure with high orientation, and accordingly, electrical conductivity and thermal conductivity may be enhanced.

Referring to the enlarged view of FIG. 7, which is an enlarged view of a partial area of the plate-shaped alloy powder 530, each of the alloy powder 530 may include a plate-shaped particle 531 and a plurality of fine particles 532 at least partially inserted on the plate-shaped particle 531. The plate-shaped particle 531 is formed by passing through the disks 621 of the secondary crushing equipment 620, and thermoelectric leg 110 formed therethrough may have enhanced orientation and electrical conductivity. Fine particles 532 crushed smaller (e.g., thinner and finer) than the plate-shaped particle 531 may be disposed on the surface or inside of the plate-shaped particle 531. The fine particles 532 are formed by passing through the disks 621 of the secondary crushing equipment 620, and may reduce thermal conductivity in thermoelectric leg 110 formed therethrough. The fine particles 532 may be irregularly positioned in an inserted (or embedded) state on the surface or inside of the plate-shaped particle 531. For example, some of each of the fine particles 532 may be positioned inside the plate-shaped particle 531, and other portions may be positioned to be exposed outside the plate-shaped particle 531. Dozens to thousands of fine particles 532 may be positioned on the surface or inside the plate-shaped particle 531. For example, the plate-shaped particle 531 may have, on average, a length of about 200 μm or less. For example, each of the fine particles 532 may have, on average, a length of about 500 nm to 1 μm or less.

FIG. 8B illustrates thermal conductivity of alloy powder for crushing equipment, and the types of crushing equipment may be ball mill, hand grinding, and disk mill (e.g., secondary crushing equipment 620). Powders manufactured by ball mill show various shapes with irregular sizes and it may be identified that thermal conductivity illustrates an average of about 1.785 W/Mk. Powders manufactured by hand grinding show clean surfaces and plate-shaped particles, but it may be identified that PF increase is limited due to high thermal conductivity (average of about 1.708 W/Mk). In contrast, the alloy powder 530 manufactured (e.g., crushed) by the disk mill (e.g., secondary crushing equipment 620) according to an embodiment of the disclosure may be identified to show plate-shaped particles 531 similar to hand grinding while having relatively many fine particles 532 distributed on the surface. Due to this influence, thermal conductivity may be decreased (average of about 1.64 W/Mk) to enhance PF. Generally, as there are more fine particles, electrical conductivity decreases and Seebeck coefficient increases, presenting a trade-off relationship, but the structure of the alloy powder 530 generated through the disk mill may maintain high electrical conductivity while limiting (e.g., preventing or reducing) the increase in thermal conductivity, so it may be provided as a thermoelectric element material that provides enhanced thermoelectric effects.

FIG. 9 is a view illustrating power factor (PF) according to the size of alloy powder according to an embodiment of the disclosure.

According to an embodiment, a thermoelectric element (e.g., thermoelectric element 100 of FIG. 1) includes a thermoelectric leg 110 (e.g., Peltier leg) (e.g., the thermoelectric leg 110 of FIG. 1), and thermoelectric leg 110 may be formed through a plurality of processes. Hereinafter, the forming process of the thermoelectric leg 110 is an example of an N-type thermoelectric element forming process.

The configuration of the thermoelectric leg 110 of FIG. 9 may be identical in whole or part to the configuration of the thermoelectric leg 110 of FIG. 1.

The embodiments of FIG. 9 may be selectively combined with the embodiments of FIGS. 1 to 8B and FIGS. 10 to 11.

According to an embodiment, the forming process of the thermoelectric leg 110 may include a primary crushing (coarse grinding or rough grinding) process of a Bi—Te based alloy material 510 (e.g., process 200 of FIG. 4), a secondary crushing (medium grinding) process of the primarily crushed (coarse grinding or rough grinding) alloy pieces (e.g., process 300 of FIG. 4), a classification process of the secondarily crushed (medium grinding) alloy powder (e.g., process 400 of FIG. 4), and a sintering process (e.g., process 500 and process 600 of FIG. 4).

According to an embodiment, the classification process (e.g., process 400 of FIG. 4) is a process of classifying the secondarily crushed alloy powder 530 by size, and may be a preliminary process for using only the alloy powder 530 advantageous for the thermoelectric leg 110 by comparing performance (e.g., electrical conductivity, orientation) according to the size of the classified alloy powders. The performance may be identified through power factor (PF) (e.g., Seebeck coefficient).

According to an embodiment, the classification process may classify into alloy powder 530 of about 90 μm to 180 μm, alloy powder 530 of about 53 μm to 90 μm, and alloy powder 530 of about 53 μm or less, and FIG. 9 may identify the power factor (PF) in case that the sintered material 540 is formed with the classified alloy powder 530.

Referring to FIG. 9, it may be identified that the sintered material (sintered alloy) using alloy powder of about 53 μm or less has a PF value of about 2.5 to 3.0 or less. It may be identified that the sintered material (sintered alloy) using alloy powder of about 53 μm to 90 μm has a PF value of about 2.9 to 3.4 or less. It may be identified that the sintered material (sintered alloy) using alloy powder of about 90 μm to 180 μm has a PF value of 3.7 or more (e.g., about 3.9 on average).

According to an embodiment, power factor (PF) is defined by the relationship between Seebeck coefficient(S) and electrical conductivity (σ).

$$PF = {S}^{2} \cdot σ \qquad [ Formula ]$$

In the formula, S is the Seebeck coefficient, which represents the potential difference due to thermal and electrical driving, and σ is the electrical conductivity, which represents how well the material conducts electricity.

The power factor (PF) is an indicator for evaluating the electrical performance of thermoelectric elements and may play an important role in maximizing thermoelectric effects. For example, the larger the PF, the higher the efficiency of the thermoelectric element converting heat to electrical energy. For example, PF represents thermoelectric conversion efficiency of the thermoelectric element, and it may be identified through the formula that materials with better electrical performance have higher PF.

According to an embodiment of the disclosure, the sintered material (sintered alloy) using alloy powder of about 90 μm to 180 μm provides high PF, and accordingly may be provided as a thermoelectric element material that provides enhanced thermoelectric effects.

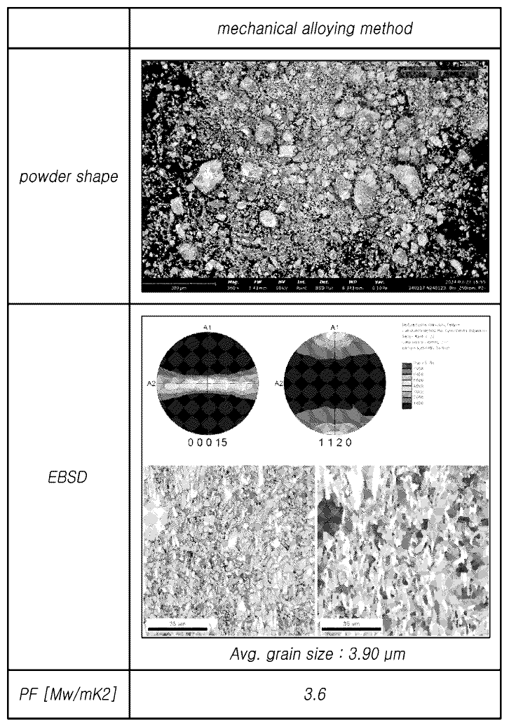

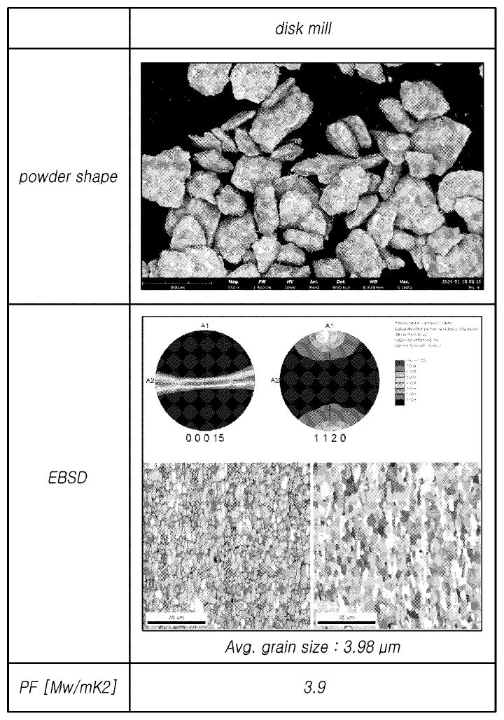

FIG. 10A is a view illustrating the shape and electron backscatter diffraction (EBSD) of powder by a general mechanical alloying method.

FIG. 10B is a view illustrating the shape and electron backscatter diffraction (EBSD) of powder by multiple crushing according to an embodiment of the disclosure.

According to an embodiment, a thermoelectric element (e.g., thermoelectric element 100 of FIG. 1) includes a thermoelectric leg 110 (e.g., Peltier leg) (e.g., the thermoelectric leg 110 of FIG. 1), and thermoelectric leg 110 may be formed through a plurality of processes. Hereinafter, the forming process of the thermoelectric leg 110 is an example of an N-type thermoelectric element forming process.

The configuration of the alloy powder 530 and sintered material 540 of the thermoelectric leg 110 of FIG. 10B may be identical in whole or part to the configuration of the alloy powder 530 and sintered material 540 of the thermoelectric leg 110 of FIGS. 1 to 9.

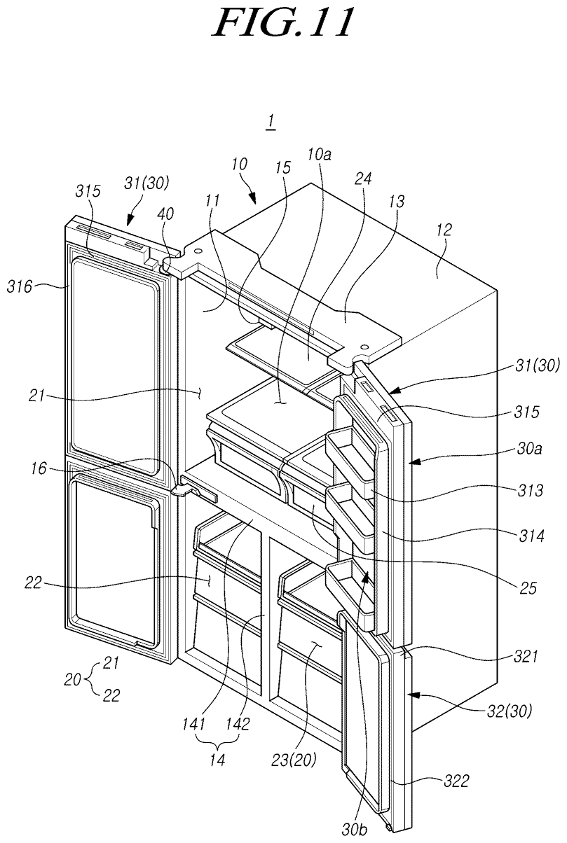

The embodiments of FIG. 10B may be selectively combined with the embodiments of FIGS. 1 to 9 and the embodiment of FIG. 11.

The electron backscatter diffraction (EBSD) of FIGS. 10A and 10B may also be named as electron backscatter diffraction pattern or electron backscatter diffraction analysis, and is generally used as a technique for analyzing the crystal structure and microstructure of materials using a scanning electron microscope (SEM). For example, EBSD is useful for investigating and visualizing the microstructure of materials such as crystal grain orientation and crystal grain size at high resolution, and may provide important information for analyzing the shape of one side of the material such as crystal planes, crystal orientations, and deformation modes.

Referring to FIG. 10A, the powder shape by a general mechanical alloying method may be identified. The powder shape of FIG. 10A is a collection of powders with irregular sizes, and the sintered material of the powders has uneven crystal grain sizes and, in case that the sintered material (sintered alloy) is formed, it may have a structure with weak orientation.

Referring to FIG. 10B, the shape of the evenly distributed plate-shaped alloy powder 530 by multiple crushing processes (e.g., secondary crushing equipment) may be identified. The plate-shaped powder shape of FIG. 10B is a collection of regular plate-shaped powders with the c-axis broken and strong bonding of the a-axis and b-axis, and the sintered material 540 (sintered alloy) of the powders may have even crystal grain sizes and a structure with strong orientation.

Referring to the EBSD of FIGS. 10A and 10B, the orientation of the crystal grains of the sintered material 540 (sintered alloy) may be identified through the (0001) plane (e.g., 00015 of the pole figure of FIGS. 10A and 10B) and (1120) plane through the pole figure. The pole figure is a tool for visually representing crystal orientation or crystal grain orientation and may show the collective distribution related to the orientation of specific crystal planes. The (0001) plane represents the base plane perpendicular to the c-axis direction, and the more the band in the center (e.g., red band) is highlighted, the better the orientation of the crystal grains. The (1120) plane is related to the a-axis direction and may be used for crystal grain arrangement or microstructure analysis.

While the (0001) plane (e.g., 00015) of the pole figure referring to the EBSD of FIG. 10A illustrates less band in the center (e.g., red band), it may be identified that the (0001) plane (e.g., 00015) of the pole figure referring to the EBSD of FIG. 10B illustrates the band in the center (e.g., red band) accurately and thickly along the center. Accordingly, it may be identified that the orientation of the sintered material 540 manufactured with the plate-shaped powder shape of the disclosure is excellent.

In the enlarged view illustrating the sintered material referring to the EBSD of FIG. 10A, crystal grains of various sizes are disposed and have an irregular shape with non-uniform directions, whereas in the enlarged view illustrating the sintered material referring to the EBSD of FIG. 10B, crystal grains of uniform size are disposed and it may be identified that they have a regular shape disposed parallel along one direction (e.g., vertical direction). Accordingly, it may be identified that the orientation of the sintered material of the plate-shaped powder shape of the disclosure is excellent.

According to an embodiment, it may be identified that the power factor (PF) value of the sintered material of FIG. 10A is about 3.6, and the power factor (PF) value of the sintered material of FIG. 10B is 3.7 or more (e.g., about 3.9 on average). Accordingly, it may be identified that the electrical conductivity of the sintered material of the plate-shaped powder shape of the disclosure is excellent.

Hereinafter, the general configuration of a refrigerator in which the thermoelectric element 100 (e.g., the thermoelectric leg 110) of the disclosure is used is described. However, the thermoelectric element 100 of the disclosure may be easily modified and applied to various home appliances in which the thermoelectric elements are utilized, such as an air purifying humidifier, a robot cleaner, a cooking device, or a washer, in addition to refrigerators.

FIG. 11 is a perspective view illustrating a refrigerator according to an embodiment of the disclosure.

Referring to FIG. 11, a refrigerator 1 may include a main body 10, a storage compartment 20, a door 30, or a cold air supply device.

According to an embodiment, the storage compartment 20 may be partitioned into several spaces inside the main body 10. The door 30 may be disposed on the front surface of the main body 10 to open and close the storage compartment 20. The cold air supply device may be provided inside the main body 10 to supply cold air to, e.g., the storage compartment 20.

According to an embodiment, the main body 10 may include an inner housing 11 and/or an outer housing 12. The inner housing 11, e.g., may be provided to form an exterior of the storage compartment 20. The inner housing 11 may be integrally injection-molded with, e.g., a plastic material. The outer housing 12, e.g., may be provided to form at least a portion of the exterior of the refrigerator 1. The outer housing 12 may be formed of, e.g., a metal material having excellent durability and aesthetics. A receiving space may be formed between the inner housing 11 and the outer housing 12. A main body insulator (not shown) for insulating the storage compartment 20 may be provided in a portion of the receiving space.

According to an embodiment, the cold air supply device may generate cold air using a cooling circulation cycle for compressing, condensing, expanding, and evaporating the refrigerant.

According to an embodiment, the storage compartment 20 may be partitioned into a plurality of compartments by a partition wall 14. The storage compartment 20 may be formed by the inner housing 11 and the partition wall 14 of the main body 10. A plurality of shelves 24 or storage containers 25 may be provided inside the storage compartment 20 to store food or the like. The plurality of shelves 24 and the storage container 25 may be, e.g., removable.

According to an embodiment, the storage compartment 20 may be divided into a plurality of storage compartments 21, 22, and 23 by the partition wall 14. For example, as illustrated, the storage compartment 20 may include one first storage compartment 21 (e.g., an upper storage compartment) positioned at an upper portion, and a second storage compartments 22 (e.g., a lower storage compartment) and a third storage compartment 23 (e.g., a lower storage compartment) positioned at a lower portion.

According to an embodiment, the partition wall 14 may include a first partition wall 141 and a second partition wall 142. The partition wall 14 may have, e.g., a T-shaped cross section. The first partition wall 141 may be provided horizontally to divide, e.g., the first storage compartment 21 and the second and third storage compartments 22 and 23. The second partition wall 142 may be provided vertically to divide, e.g., the second storage compartment 22 and the third storage compartment 23. The second partition wall 142 may be formed to protrude downward from, e.g., the first partition wall 141. The illustrated second partition wall 142 is formed to protrude from the center of the first partition wall 141, but the disclosure is not limited thereto, and the sizes of the second storage compartment 22 and the third storage compartment 23 may vary depending on the position of the second partition wall 142.

The first storage compartment 21 of the illustrated storage compartment 20 may be used as a refrigerating chamber, and the second and third storage compartments 22 and 23 may be used as freezing chambers, but the disclosure is not limited thereto, and the position and number of each of the refrigerating chamber and the freezing chamber may vary depending on the user's needs.

According to an embodiment, the number, size, or shape of the storage compartment 20 may vary depending on the shape or position of the partition wall 14. The freezing compartment may be maintained at about minus 20 degrees Celsius, and the refrigerating compartment may be maintained at about 3 degrees Celsius. The storage compartment 20 may be insulated by, e.g., a partition wall 14.

According to an embodiment, the storage compartment 20 may be partitioned left and right by one vertical partition wall. Here, the vertical partition wall may be formed so that one end is in contact with the upper portion of the inner housing 11 and the other end is in contact with the lower portion of the inner housing 11. The size of the storage compartment 20 partitioned left and right may vary depending on the position of the vertical partition wall. For example, the storage compartment 20 having the vertical partition wall provided in the middle and partitioned left and right may be provided in mirror symmetry. According to an embodiment, there may be a plurality of vertical partition walls. In case that there are a plurality of vertical partition walls, three or more storage compartments 20 may be provided in the left-right direction.

According to an embodiment, the storage compartment 20 may be partitioned up and down only by one horizontal partition wall. In other words, the storage compartment 20 may be partitioned into two, e.g., the upper storage compartment and the lower storage compartment. Here, the horizontal partition wall may be formed so that one end thereof is in contact with the left portion of the inner housing 11 and the other end thereof is in contact with the right portion of the inner housing 11. The size of the storage compartment 20 partitioned up and down may vary depending on the position of the horizontal partition wall. According to an embodiment, there may be a plurality of horizontal partition walls. In case that there are a plurality of horizontal partition walls, three or more storage compartments 20 may be provided in the up-down direction. In addition to the above-described embodiment, a plurality of storage compartments 20 of various types may be configured according to the shape and number of partition walls 14.

According to an embodiment, the door 30 may include a first door 31 (e.g., an upper door) or a second door 32 (e.g., a lower door) as illustrated. The door 30 may be provided to open and close, e.g., the opening 10a of the main body 10. For example, a pair of first doors 31 (e.g., double door type) may be provided to open and close the first storage compartment 21. A pair of second doors 32 (e.g., double door type) may be provided to open or close, e.g., the second storage compartment 22 or the third storage compartment 23. Further, the number and shape of the doors 30 may vary depending on the number and shape of the storage compartment 20, and the door 30 may be configured in a sliding manner as well as a manner of rotating about the hinge 16.

According to an embodiment, a rotating bar 316 may be provided on one of the pair of first doors 31. The rotating bar 316 may be disposed, e.g., on a side opposite to a side of one of the pair of first doors 31 forming a rotation shaft. The rotation bar 316 may be provided such that, e.g., a rotation shaft is fixed to a side surface of one of the pair of first doors 31 to be rotatable about the rotation shaft. The rotating bar 316 may be provided to be positioned in the middle of the front surface of the main body 10 in case that one of the pair of first doors 31 is in a closed state. The rotating bar 316 may seal a gap between the pair of first doors 31 in case that the pair of first doors 31 are closed. The main body 10 may be provided with a rotating bar guide 15 for guiding the movement of the rotating bar 316 in case that one of the pair of first doors 31 is closed.

According to an embodiment, the door 30 (e.g., the first door 31 or the second door 32) may include a door panel 30a or a door body 30b. The door panel 30a and the door body 30b may be detachably coupled to each other.

According to an embodiment, for example, one side of the door body 30b may be fixed to the main body 10 by the hinge 16. The door body 30b may be provided to be rotatable about the main body 10. The door panel 30a may form, e.g., a portion of the front exterior of the refrigerator 1. The door panel 30a may play an important role for aesthetics, especially in case that the refrigerator 1 is disposed indoors. Accordingly, the user may decorate the front exterior of the refrigerator 1 as desired by replacing it with a door panel 30a having a different color or design. According to an embodiment, the door panel 30a and the door body 30b may be integrally formed with each other.

Hereinafter, for convenience of description, only one first door 31 and one second door 32 are described, and a description of the remaining first door 31 and the remaining second door 32 is omitted. However, the first door 31 and the second door 32, which are not described, may be substantially the same as the first door 31 and the second door 32, which are described below, except that they are provided to be in mirror symmetry to each other. Further, the same configuration as that of the first door 31 may be applied to the second door 32, and a detailed description thereof may be omitted.

According to an embodiment, the first door 31 may include a first door handle (not shown), a first door shelf 313, a first shelf support 314, or a first gasket 315. The first door 31 may be rotatably coupled to the main body 10 to open and close at least a portion of the first storage compartment 21. The user may open and close the first door 31 using the first door handle. The first door handle may be recessed in the bottom surface of the first door 31 or may protrude from the front surface of the first door 31, but the disclosure is not limited thereto.

According to an embodiment, the first door shelf 313 may be provided to receive, e.g., food. First shelf supports 314 may be provided on both left and right sides of the first door shelf 313 to support the first door shelf 313. The first shelf support 314 may extend vertically from, e.g., the first door 31. In other words, the first shelf support 314 may be provided to protrude backward from the rear surface of the first door 31 and extend in the up-down direction. For example, the first shelf support 314 may be detachably provided on the first door 31 as a separate component, or may be integrally formed with the first door 31. The first shelf support 314 may be formed to protrude rearward from, e.g., the rear surface of the door body 30b.

According to an embodiment, the first gasket 315 may be provided to surround, e.g., a rear edge of the first door 31. Specifically, the first gasket 315 may be provided to surround an edge of the door body 30b. The first gasket 315 may be provided to seal a gap with the main body 10 in a state in which the first door 31 is closed.

According to an embodiment, the second door 32 may include a second door handle 321 or a second gasket 322. The second door 32 may be rotatably coupled to the main body 10 to open and close the second storage compartment 22 or the third storage compartment 23. The user may open and close the second door 32 using the second door handle 321. The second door handle 321 may be recessed in the upper surface of the second door 32 or may protrude from the front surface of the second door 32, but the disclosure is not limited thereto.

According to an embodiment, the second gasket 322 may be provided to surround, e.g., a rear edge of the second door 32. The second gasket 322 may be provided to seal a gap with the main body 10 in a state in which the second door 32 is closed.

Although not illustrated, the second door 32 may further include all or some of the same components as the first door shelf 313 and the first shelf support 314 of the first door 31.

According to an embodiment, the refrigerator 1 may include a top table 13 provided on an upper portion of the main body 10. The top table 13 may be coupled to an upper portion of the outer housing 12. For example, the top table 13 may be coupled to the upper surface of the outer housing 12. For example, the top table 13 may be fixed to the outer housing 12.

According to an embodiment, the top table 13 may cover the hinge bracket 40 of the upper door. In this sense, the top table 13 may be referred to as a hinge bracket cover.

According to an embodiment, the top table 13 may cover various electronic components. A receiving space in which various electronic components are received may be formed inside the top table 13. For example, the top table 13 may cover the door driver (not illustrated), and the door driver (not illustrated) may be received inside the top table 13.

Although the refrigerator 1 according to an embodiment of the disclosure has been described as an example of the disclosure assuming that the refrigerator 1 is an indirect cooling-type refrigerator, the spirit of the disclosure is not limited thereto and may also be applied to a direct cooling-type refrigerator.

Generally, a thermoelectric element may include thermoelectric legs divided into N-type and P-type. The N-type thermoelectric leg may be provided as a high-efficiency thermoelectric element as the orientation and electrical conductivity are better. However, in an N-type Peltier element having a hexagonal (HCP) crystal structure, the HCP crystal structure may not uniformly control the impact energy applied from the outside due to the c-axis having weak van der Waals bonding. In case that the alloy material is crushed, it is formed into powders having non-uniform powder sizes and irregular powder shapes, which may be difficult to utilize as a high-efficiency thermoelectric element.

A thermoelectric element according to an embodiment of the disclosure may maximize the generation of plate-shaped particles with resolved c-axis weakness through multiple specific crushing processes. Accordingly, a thermoelectric element with enhanced orientation and electrical conductivity may be provided.

A thermoelectric element according to an embodiment of the disclosure may secure high production speed and powder uniformity by providing plate-shaped alloy powder using multiple simple crushing processes.

A thermoelectric element according to an embodiment of the disclosure forms a sintered material in which plate-shaped alloy powder is bonded, enhancing internal stress, and accordingly may provide stable and efficient thermoelectric performance to home appliances (e.g., refrigerators).

Effects obtainable from the disclosure are not limited to the above-mentioned effects, and other effects not mentioned may be apparent to one of ordinary skill in the art from the following description.

A method for manufacturing a thermoelectric element 100 according to an embodiment of the disclosure may comprises preparing a Bi—Te based alloy material 510 that includes Se in a range of 0.1 to 0.5 mol. % based on total moles of the Bi—Te based alloy material, primarily crushing the Bi—Te based alloy material 510 between a pair of crushing plates 611 having a gap between the crushing plates set to 1 mm to 5 mm, so as to form primarily crushed alloy pieces having a first length L1, and secondarily crushing the primarily crushed alloy pieces 520 between a pair of disks 621 having a gap between the disks set to 0.1 mm to 10 mm, so as to form an alloy powder including plate-shaped alloy powder 530 having a second length L2 smaller than the first length L1.

According to an embodiment, in the secondary crushing, of the pair of disks 621 facing each other, a first disk 621a may be in a stationary state, and a second disk 621b may be in a rotating state. The rotation speed of the second disk 621b may be set to 440 RPM to form the plate-shaped alloy powder 530.

According to an embodiment, the first length L1 of the primarily crushed alloy pieces 520 may be 20 mm to 40 mm.

According to an embodiment, the second length L2 of the secondarily crushed plate-shaped alloy powder 530 may be 200 μm or less.

According to an embodiment, the size of the Bi—Te based alloy material 510 may have a diameter Φ of 25 mm to 40 mm and a length L of 50 mm to 300 mm.

According to an embodiment, the method for manufacturing a thermoelectric element may further include classifying the plate-shaped alloy powder 530 according to size, and forming the classified plate-shaped alloy powder 530 into a sintered material, by press forming and hot extrusion to form thermoelectric legs 110 for the thermoelectric element.

According to an embodiment, by the forming of the classified plate-shaped alloy powder into the sintered material, crystal grains of the sintered material may be configured to be oriented in a parallel direction.

According to an embodiment, the grain size of each crystal grain of the sintered material may be 2.0 μm to 5.0 μm.

According to an embodiment, the power factor (PF) value of the plate-shaped alloy powder 530 constituting the sintered material may be 3.7 or more (e.g., about 3.9 on average).

According to an embodiment, in the primary crushing, the amount of the Bi—Te based alloy material 510 to be input between the crushing plates 611 may be 50 g to 200 g.

According to an embodiment, in the secondary crushing, the amount of the alloy pieces 520 to be input between the disks 621 may be 50 g to 200 g.

A refrigerator 1 according to an embodiment of the disclosure may include a main body 10, a door 30 rotatably connected to open and close the main body, a storage compartment 20 disposed inside the main body and storing food, and a cold air supply device configured to supply cold air to the storage compartment and including a thermoelectric element 100. The thermoelectric element may include a Bi—Te based thermoelectric leg 110. The Bi—Te based thermoelectric leg 110 may include Se in a range of 0.1 to 0.5 mol. % based on total moles of the Bi—Te based thermoelectric leg, the Bi—Te based thermoelectric leg is a sintered material composed of plate-shaped alloy powder 530. The length of each of the plate-shaped alloy powder 530 forming the sintered material may be 200 μm or less.

According to an embodiment, each of the alloy powder 530 comprising the Bi—Te based thermoelectric leg may include a plate-shaped particle 531 and a plurality of fine particles 532 at least partially inserted on the surface of the plate-shaped particle 531.

According to an embodiment, the length of each of the plurality of fine particles 532 may be 500 nm to 1 μm.

According to an embodiment, the Bi—Te based thermoelectric leg 110 may form an N-type thermoelectric leg.

According to an embodiment, crystal grains of the sintered alloy (e.g., sintered material) may be configured to be oriented in a parallel direction.

According to an embodiment, the PF value of the sintered alloy (e.g., sintered material) may be 3.7 or more (e.g., about 3.9 on average).

According to an embodiment, the grain size of each crystal grain of the sintered alloy (e.g., sintered material) may be 2.0 μm to 5.0 μm.

According to an embodiment, the alloy powder 530 for constituting the sintered material may be formed through multiple crushing processes.

A thermoelectric element according to an embodiment of the disclosure may include a Bi—Te based thermoelectric leg 110. The Bi—Te based thermoelectric leg 110 may include selenium (Se) in a range of 0.1 to 0.5 mol. % based on total moles of the Bi—Te based thermoelectric leg. The Bi—Te based thermoelectric leg 110 may be a sintered material composed of plate-shaped alloy powder 530. The grain size of the plate-shaped alloy powder 530 forming the sintered material may be 90 μm to 180 μm.

1. A method for manufacturing a thermoelectric element, the method comprising:
preparing a Bi—Te based alloy material that includes Se in a range of 0.1 to 0.5 mol. % based on total moles of the Bi—Te based alloy material;
primarily crushing the Bi—Te based alloy material between a pair of crushing plates having a gap between the crushing plates set to 1 mm to 5 mm, so as to form primarily crushed alloy pieces having a first length; and
secondarily crushing the primarily crushed alloy pieces between a pair of disks having a gap between the disks set to 0.1 mm to 10 mm, so as to form an alloy powder including plate-shaped alloy powder having a second length smaller than the first length.

2. The method of claim 1, wherein
in the secondarily crushing,
of the pair of disks facing each other,
a first disk is in a stationary state, and
a second disk is in rotational motion, and
wherein a rotation speed of the second disk is set to 440 RPM to form the plate-shaped alloy powder.

3. The method of claim 1, wherein
the first length of the primarily crushed alloy pieces is 20 mm to 40 mm.

4. The method of claim 1, wherein
the second length of the secondarily crushed plate-shaped alloy powder is 200 μm or less.

5. The method of claim 1, wherein
a size of the Bi—Te based alloy material has a diameter of 25 mm to 40 mm, and a length of 50 mm to 300 mm.

6. The method of claim 1, further comprising:
classifying the plate-shaped alloy powder according to size; and
forming the classified plate-shaped alloy powder into a sintered material by press forming and hot extrusion to form thermoelectric legs for the thermoelectric element.

7. The method of claim 6, wherein
by the forming of the classified plate-shaped alloy powder into the sintered material, crystal grains of the sintered material are configured to be oriented in a parallel direction.

8. The method of claim 6, wherein
a grain size of each crystal grain of the sintered material is 2.0 μm to 5.0 μm.

9. The method of claim 6, wherein
a power factor value of the sintered material is 3.7 or more on average.

10. The method of claim 1, wherein
in the primarily crushing, an amount of the Bi—Te based alloy material to be input between the crushing plates is 50 g to 200 g.

11. The method of claim 1, wherein
in the secondarily crushing, an amount of the alloy pieces to be input between the disks is 50 g to 200 g.

12. A refrigerator comprising:
a main body;
a door rotatably connected to open or close the main body;
a storage compartment disposed inside the main body for storing food; and
a cold air supply device configured to supply cold air to the storage compartment, and including a thermoelectric element, wherein the thermoelectric element including:
a Bi—Te based thermoelectric leg,
wherein the Bi—Te based thermoelectric leg includes Se in a range of 0.1 to 0.5 mol. % based on total moles of the Bi—Te based thermoelectric leg,
the Bi—Te based thermoelectric leg is a sintered material composed of plate-shaped alloy powder, and
a length of each of the plate-shaped alloy powder forming the sintered material is 200 μm or less.

13. The refrigerator of claim 12, wherein
each of the alloy powder comprising the Bi—Te based thermoelectric leg includes a plate-shaped particle, and a plurality of fine particles at least partially inserted on a surface of the plate-shaped particle.

14. The refrigerator of claim 13, wherein
a length of each of the plurality of fine particles is 500 nm to 1 μm.

15. The refrigerator of claim 12, wherein
the Bi—Te based thermoelectric leg forms an N-type thermoelectric leg.

16. The refrigerator of claim 12, wherein
crystal grains of the sintered material are configured to be oriented in a parallel direction.

17. The refrigerator of claim 12, wherein
a power factor value of the sintered material is 3.7 or more on average.

18. The refrigerator of claim 12, wherein
a grain size of each crystal grain of the sintered material is 2.0 μm to 5.0 μm.

19. The refrigerator of claim 12, wherein
the alloy powder constituting the sintered material is formed through multiple crushing processes.

20. A thermoelectric element comprising:
a Bi—Te based thermoelectric leg,
wherein the Bi—Te based thermoelectric leg includes Se in a range of 0.1 to 0.5 mol. % based on total moles of the Bi—Te based thermoelectric leg,
the Bi—Te based thermoelectric leg is a sintered material composed of plate-shaped alloy powder, and
a length of each of the plate-shaped alloy powder forming the sintered material is 200 μm or less.
